(19) United States
(12) Patent Application Publication
(10) Pub. No.: US 2023/0077018 A1
(43) Pub. Date: Mar. 9, 2023

(54) CONDUCTIVE AND FLEXIBLE SANDWICH-STRUCTURED COMPOSITES

(71) Applicants: Hongbin Yu, Chandler, AZ (US); Yanze Wu, Sunnyvale, CA (US); Todd Houghton, Tempe, AZ (US); Mayukh Nandy, Tempe, AZ (US)

(72) Inventors: Hongbin Yu, Chandler, AZ (US); Yanze Wu, Sunnyvale, CA (US); Todd Houghton, Tempe, AZ (US); Mayukh Nandy, Tempe, AZ (US)

(21) Appl. No.: 17/930,222

(22) Filed: Sep. 7, 2022

Related U.S. Application Data
(60) Provisional application No. 63/241,449, filed on Sep. 7, 2021.

(51) Int. Cl. H01L 23/532; B29C 39/00; B29C 39/12; B29C 39/38; H01L 21/768

(52) U.S. Cl. CPC H01L 23/5328; B29C 39/003; B29C 39/123; B29C 39/38; H01L 23/53242; H01L 21/76838; B29K 2083/00

(57) ABSTRACT

Interconnects may comprise a sandwich-structured composite comprising a core layer located between two thermosetting polymer layers. The core layer may comprise 80 wt % to 95 wt % conductive metal and a polymer. The conductive metal may comprise silver (Ag). The polymer may comprise polydimethylsiloxane (PDMS). Interconnects may be particularly suited for use in electronic devices, such as a flexible batteries and wearable electronic devices.

### CROSS-REFERENCE TO RELATED APPLICATION(S)

This application claims priority to U.S. Provisional Application No. 63/241,449 filed on Sep. 7, 2021, the entire contents of which are incorporated herein by reference.

### TECHNICAL FIELD

The present disclosure relates to materials, methods, and techniques for interconnects. Exemplary interconnects may be incorporated into electronic devices.

### INTRODUCTION

The field of stretchable electronics has grown tremendously in recent years with the rapid adoption of digital technologies and increasing demand for electronics. To meet the demand, electronic devices are beginning to shift from rigid structures to stretchable formats to allow electronic devices to conform better to the human body, with various applications in epidermal electronic devices, biomedical engineering, healthcare monitoring, soft robotics, electronic skins, and human-machine interfaces.

### SUMMARY

In one aspect, an interconnect is disclosed. The interconnect may comprise a sandwich-structured composite, comprising a first thermosetting polymer layer, a second thermosetting polymer layer, and a core layer between two thermosetting layers. The core layer may comprise 80 weight % (wt %) to 95 wt % conductive metal and a polymer. Each thermosetting polymer layer may comprise polydimethylsiloxane (PDMS). The conductive metal may comprise silver (Ag) flakes. The polymer may comprise polydimethylsiloxane (PDMS). The core layer may have a thickness between 50 μm and 110 μm. The sandwich-structured composite may have a thickness between 150 μm and 350 μm. In some instances, the sandwich-structured composite may have a thickness between 200 μm and 300 μm. The core layer may have a conductivity of at least 1.05*10⁵ S·cm⁻¹. The sandwich-structured composite may be capable of being stretched to 120% of an original length of the sandwich-structured composite at 50% strain without losing electrical properties.

In another aspect, an electronic device comprising an interconnect is disclosed. The interconnect may comprise a sandwich-structured composite, comprising a first thermosetting polymer layer, a second thermosetting polymer layer, and a core layer between two thermosetting layers, the core layer comprising 80 wt % to 95 wt % silver (Ag) and polydimethylsiloxane (PDMS). The interconnect may connect at least two circuit elements in an integrated circuit (IC). The first thermosetting polymer layer and the second thermosetting polymer layer may comprise polydimethylsiloxane (PDMS). In some aspects, the core layer may comprise 80 wt % to 90 wt % silver (Ag). The silver (Ag) may be present in the form of flakes.

In another aspect, a method of making an interconnect is disclosed. The method may comprise pouring a first thermosetting polymer mixture into a first mold to form a first thermosetting polymer layer, the first thermosetting polymer mixture comprising a first thermosetting polymer and a first curing agent. The method may further comprise curing the first thermosetting polymer layer. Curing the first thermosetting polymer layer may occur at a temperature between 20° C. and 150° C. Curing the first thermosetting polymer layer may occur for a time period of 10 minutes to 48 hours. The method may further comprise preparing a core layer mixture, the core layer mixture comprising 80 wt % to 95 wt % conductive metal, a polymer, and a solvent, pouring the core layer mixture onto the first thermosetting layer to form a core layer, and drying the core layer. The method may further comprise pouring a second thermosetting polymer mixture onto the core layer to form a second thermosetting polymer layer, the second thermosetting polymer mixture comprising a second thermosetting polymer and a second curing agent. The method may further comprise curing the second thermosetting polymer layer. Curing the second thermosetting polymer layer may occur at a temperature between 20° C. and 30° C. Curing the second thermosetting polymer layer may occur for a time period of 60 hours to 80 hours. The first thermosetting polymer and the second thermosetting polymer may each be PDMS. In some instances, a method of making an electronic device may comprise the method of making an interconnect

Before any embodiments of the disclosure are explained in detail, it is to be understood that the disclosure is not limited in its application to the details of construction and the arrangement of components set forth in the following description or illustrated in the following drawings. The disclosure is capable of other embodiments and of being practiced or of being carried out in various ways.

### BRIEF DESCRIPTION OF THE DRAWINGS

FIG. 1 schematically illustrates an exemplary conductive, flexible interconnect comprising a sandwich-structured composite with different layers.

FIG. 2 schematically illustrates an exemplary method of preparing an exemplary core layer mixture (a composite paste comprising silver (Ag) and polydimethylsiloxane (PDMS) in methyl isobutyl ketone (MIBK) solvent (Ag-PDMS composite in MIBK)).

FIG. 3A schematically shows PDMS and a curing agent spin-coated on a petri dish to form an exemplary first thermosetting polymer layer (the first PDMS layer).

FIG. 3B schematically shows copper (Cu) tabs placed on top of partially cured polydimethylsiloxane (PDMS) such that only the bottom surfaces of the Cu tabs are attached to the PDMS layer when the first PDMS layer is fully cured. The top surfaces of the Cu tabs are left exposed for contact with the core layer.

FIG. 3C schematically shows an exemplary core layer mixture (Ag-PDMS composite in MIBK) spin-coated on the top surfaces of the Cu tabs on the first PDMS layer.

FIG. 3D schematically shows a PDMS and curing agent mixture spin coated as an exemplary second thermosetting polymer layer (second PDMS layer) and cured.

FIG. 4A is a photograph of the top layer view of an exemplary sandwich-structured composite that was peeled out of petri-dish.

FIG. 4B is a photograph of the bottom layer view of an exemplary sandwich-structured composite that was peeled out of petri-dish.

FIG. 5A is a photograph of an exemplary sandwich-structured composite clamped between two beams in between two polycarbonate sheets in Bending Fatigue Testing Machine when there is no bending.

FIG. 5B is a photograph of the side-view of bending the exemplary sandwich-structured composite of FIG. 5A over the edge of the lower beam at 90°.

FIG. 5C shows the plot of ΔR/Ro vs. bending cycles at 90° for the exemplary sandwich-structured composite of FIG. 5A.

FIG. 6A is a photograph of a stretch test apparatus where an exemplary sandwich-structured composite is clamped between two ends of the textile analyzer. The base is fixed, and the top clamp moves vertically to apply stress on the material.

FIG. 6B shows a plot of ΔR/Ro against the number of stretching cycles at 50% strain for the exemplary sandwich-structured composite of FIG. 5A.

FIG. 7A schematically shows the top view of an exemplary sandwich-structured composite, illustrating the dimensions of the different layers and the Cu tabs.

FIG. 7B schematically illustrate an exemplary PET mold on a glass substrate that is used for preparing a sandwich-structured composite.

FIG. 8A is a photograph of the top view of an exemplary sandwich-structured composite.

FIG. 8B is a photograph showing the thickness of the different layers of an exemplary sandwich-structured composite under an optical microscope.

### DETAILED DESCRIPTION

Exemplary materials, methods and techniques disclosed and contemplated herein generally relate to interconnects comprising a sandwich-structured composite. Exemplary interconnects may be particularly suited for use in electronic devices.

Unless otherwise defined, all technical and scientific terms used herein have the same meaning as commonly understood by one of ordinary skill in the art. In case of conflict, the present document, including definitions, will control. Methods and materials are described below, although methods and materials similar or equivalent to those described herein can be used in practice or testing of the present disclosure. All publications, patent applications, patents and other references mentioned herein are incorporated by reference in their entirety. The materials, methods, and examples disclosed herein are illustrative only and not intended to be limiting.

The terms “comprise(s),” “include(s),” “having,” “has,” “can,” “contain(s),” and variants thereof, as used herein, are intended to be open-ended transitional phrases, terms, or words that do not preclude the possibility of additional acts or structures. The singular forms “a,” “an” and “the” include plural references unless the context clearly dictates otherwise. The present disclosure also contemplates other embodiments “comprising,” “consisting of” and “consisting essentially of,” the embodiments or elements presented herein, whether explicitly set forth or not.

As used herein, the term “about” is used to indicate that exact values are not necessarily attainable. Therefore, the term “about” is used to indicate this uncertainty limit. The term “about” may refer to plus or minus 10% of the indicated number. For example, “about 10%” may indicate a range of 9% to 11%, and “about 1” may mean from 0.9-1.1. Other meanings of “about” may be apparent from the context, such as rounding off, so, for example “about 1” may also mean from 0.5-1.4. The modifier “about” should also be considered as disclosing the range defined by the absolute values of the two endpoints. For example, the expression “from about 2 to about 4” also discloses the range “from 2 to 4.”

For the recitation of numeric ranges herein, each intervening number there between with the same degree of precision is contemplated. For example, for the range of 6-9, the numbers 7 and 8 are contemplated in addition to 6 and 9, and for the range 6.0-7.0, the numbers 6.0, 6.1, 6.2, 6.3, 6.4, 6.5, 6.6, 6.7, 6.8, 6.9, and 7.0 are contemplated. For another example, when a pressure range is described as being between ambient pressure and another pressure, a pressure that is ambient pressure is expressly contemplated.

As used herein, an “interconnect,” is a structure that is capable of electrically connecting two or more circuit elements in an integrated circuit (IC).

### I. EXEMPLARY COMPOSITIONS

Exemplary interconnects may comprise a sandwich-structured composite. Exemplary sandwich-structured composites may comprise a core layer located between two thermosetting polymer layers. Various aspects of exemplary core layers and sandwich-structured composites are discussed below.

A. Exemplary Core Layers

Exemplary core layers may comprise a conductive metal and a polymer. Exemplary conductive metals may include any metal capable of providing electrically conductive properties to the core layer. For instance, exemplary conductive materials include, but are not limited to, silver (Ag), iron (Fe), copper (Cu), nickel (Ni), chromium (Cr), gold (Au), platinum (Pt), palladium (Pd), aluminum (Al), and combinations thereof. In various instances, the conductive metal may comprise silver (Ag).

Exemplary conductive metals may be in the form of flakes, wires, spheres, and combinations thereof. In various instances, the conductive metal may be in the form of flakes.

The average particle size of the conductive metal may vary. In various instances, the average particle size of the conductive metal may be between 4 μm and 12 μm. In various instances, the average particle size of the conductive metal may be between 5 μm and 12 μm; between 6 μm and 12 μm; between 7 μm and 11 μm; between 8 μm and 11 μm; between 8 μm and 10 μm; or between 9 μm and 10 μm. In various instances, the average particle size of the conductive metal may be no greater than 12 μm; no greater than 11 μm; no greater than 10 μm; no greater than 9 μm; no greater than 8 μm; no greater than 7 μm; no greater than 6 μm; no greater than 5 μm; or no greater than 4 μm. In various instances, the average particle size of the conductive metal may be no less than 4 μm; no less than 5 μm; no less than 6 μm; no less than 7 μm; no less than 8 μm; no less than 9 μm; no less than 10 μm; no less than 11 μm; or no less than 12 μm.

The amount of conductive metal present in the core layer may vary. In various instances, the conductive metal may be present in the core layer at 80 weight % (wt %) to 95 wt % of the total weight of the core composite layer. In various instances, the conductive metal may be present in the core layer at 80 wt % to 90 wt %; 81 wt % to 89 wt %; 82 wt % to 88 wt %; 83 wt % to 87 wt %; or 84 wt % to 86 wt %. In various instances, the conductive metal may be present in the core layer at no greater than 95 wt %; no greater than 90 wt %; no greater than 89 wt %; no greater than 87 wt %; no greater than 86 wt %; no greater than 85 wt %; no greater than 84 wt %; no greater than 83 wt %; no greater than 82 wt %; no greater than 81 wt %; or no greater than 80 wt %. In various instances, the conductive metal may be present in the core layer at no less than 80 wt %; no less than 81 wt %; no less than 82 wt %; no less than 83 wt %; no less than 84 wt %; no less than 85 wt %; no less than 86 wt %; no less than 87 wt %; no less than 88 wt %; no less than 89 wt %; no less than 90 wt %; or no less than 95 wt %.

Exemplary core layers may comprise any polymer suitable for forming an electrically conductive layer with the conductive metal, including, but not limited to, thermoplastic polymers, thermosetting polymers, and combinations thereof. In various instances, the core layer may comprise polydimethylsiloxane (PDMS).

The amount of polymer present in the core layer may vary. In various instances, the polymer may be present in the core layer at 5 wt % to 20 wt %. In various instances, the polymer may be present in the core layer at 10 wt % to 20 wt %; 11 wt % to 19 wt %; 12 wt % to 18 wt %; 13 wt % to 17 wt %; or 14 wt % to 16 wt %. %. In various instances, the polymer may be present in the core layer at no greater than 20 wt %; no greater than 19 wt %; no greater than 18 wt %; no greater than 17 wt %; no greater than 16 wt %; no greater than 15 wt %; no greater than 14 wt %; no greater than 13 wt %; no greater than 12 wt %; no greater than 11 wt %; no greater than 10 wt %; or no greater than 5 wt %. In various instances, the polymer may be present in the core layer at no less than 5 wt %; no less than 10 wt %; no less than 11 wt %; no less than 12 wt %; no less than 13 wt %; no less than 14 wt %; no less than 15 wt %; no less than 16 wt %; no less than 17 wt %; no less than 18 wt %; no less than 19 wt %; or no less than 20 wt %.

Exemplary core layers may have a thickness between 50 μm and 110 μm. In various instances, the core layer has a thickness between 55 μm and 105 μm; between 60 μm and 100 μm; between 65 μm and 95 μm; between 70 μm and 90 μm; or between 75 μm and 85 μm. In various instances, the core layer may have a thickness of no greater than 110 μm; no greater than 100 μm; no greater than 95 μm; no greater than 90 μm; no greater than 85 μm; no greater than 80 μm; no greater than 75 μm; no greater than 70 μm; no greater than 65 μm; no greater than 60 μm; no greater than 55 μm; or no greater than 50 μm. In various instances, the core layer may have a thickness of no less than 50 μm; no less than 55 μm; no less than 60 μm; no less than 65 μm; no less than 70 μm; no less than 75 μm; no less than 80 μm; no less than 85 μm; no less than 90 μm; no less than 95 μm; no less than 100 μm; no less than 105 μm; or no less than 110 μm.

Exemplary core layers may have a conductivity of 1.00*10⁵ S·cm⁻¹ to 1.10*10⁵ S·cm⁻¹. In various instances, exemplary core layers may have a conductivity of no greater than 1.10*10⁵ S·cm⁻¹; no greater than 1.09*10⁵ S·cm⁻¹; no greater than 1.08*10⁵ S·cm⁻¹; no greater than 1.07*10⁵ S·cm⁻¹; no greater than 1.06*10⁵ S·cm⁻¹; no greater than 1.05*10⁵ S·cm⁻¹; no greater than 1.04*10⁵ S·cm⁻¹; no greater than 1.03*10⁵ S·cm⁻¹; no greater than 1.02*10⁵ S·cm⁻¹; no greater than 1.01*10⁵ S·cm⁻¹; or no greater than 1.00*10⁵ S·cm⁻¹. In various instances, exemplary core layers may have a conductivity of at least 1.00*10⁵ S·cm⁻¹; at least 1.01*10⁵ S·cm⁻¹; at least 1.02*10⁵ S·cm⁻¹; at least 1.03*10⁵ S·cm⁻¹; at least 1.04*10⁵ S·cm⁻¹; at least 1.05*10⁵ S·cm⁻¹; at least 1.06*10⁵ S·cm⁻¹; at least 1.07*10⁵ S·cm⁻¹; at least 1.08*10⁵ S·cm⁻¹; at least 1.09*10⁵ S·cm⁻¹; or at least 1.10*10⁵ S·cm⁻¹.

Exemplary core layers may have a resistivity of 5μΩ-cm to 15 μΩ-cm. In various instances, core layer may have a resistivity of 6μΩ-cm to 14 μΩ-cm; 7μΩ-cm to 13 μΩ-cm; 8 μΩ-cm to 12 μΩ-cm; or 9μΩ-cm to 11 μΩ-cm. In various instances, core layer may have a resistivity of no greater than 15 μΩ-cm; no greater than 14 μΩ-cm; no greater than 13 μΩ-cm; no greater than 12 μΩ-cm; 11 μΩ-cm; no greater than 10 μΩ-cm; no greater than 9μΩ-cm; no greater than 8μΩ-cm; no greater than 7μΩ-cm; no greater than 6μΩ-cm; or no greater than 5μΩ-cm. In various instances, core layer may have a resistivity of no less than 5μΩ-cm; no less than 6 μΩ-cm; no less than 7μΩ-cm; no less than 8μΩ-cm; no less than 9μΩ-cm; no less than 10 μΩ-cm; no less than 11 μΩ-cm; no less than 12 μΩ-cm; no less than 13 μΩ-cm; no less than 14 μΩ-cm; or no less than 15 μΩ-cm.

B. Exemplary Sandwich-Structured Composites

Exemplary sandwich-structured composites may comprise a core layer located between two thermosetting polymer layers. As used herein, a “thermosetting polymer,” is a polymer obtained by irreversibly hardening (“curing”) a soft solid or a viscous liquid prepolymer (resin). Exemplary thermosetting polymer layers comprise a thermosetting polymer such as, but not limited to, polydimethylsiloxane (PDMS), polyurethane, epoxy, and combinations thereof. In various instances, both thermosetting polymer layers comprise PDMS.

Exemplary sandwich-structured composites may have a thickness between 150 μm and 350 μm. In various instances, the sandwich-structured composite has a thickness between 160 and 340 μm; between 170 μm and 330 μm; between 180 μm and 320 μm; between 190 μm and 310 μm; between 200 μm and 300 μm; between 210 μm and 290 μm; between 220 μm and 280 μm; between 230 μm and 270 μm; or between 240 μm and 260 μm. In various instances, the sandwich-structured composite has a thickness of no greater than 350 μm; no greater than 340 μm; no greater than 330 μm; no greater than 320 μm; no greater than 310 μm; no greater than 300 μm; no greater than 290 μm; no greater than 280 μm; no greater than 270 μm; no greater than 260 μm; no greater than 250 μm; no greater than 240 μm; no greater than 230 μm; no greater than 220 μm; no greater than 210 μm; no greater than 200 μm; no greater than 190 μm; no greater than 180 μm; no greater than 170 μm; no greater than 160 μm; or no greater than 150 μm. In various instances, the sandwich-structured composite has a thickness of no less than 150 μm; no less than 160 μm; no less than 170 μm; no less than 180 μm; no less than 190 μm; no less than 200 μm; no less than 210 μm; no less than 220 μm; no less than 230 μm; no less than 240 μm; no less than 250 μm; no less than 260 μm; no less than 270 μm; no less than 280 μm; no less than 290 μm; no less than 300 μm; no less than 310 μm; no less than 320 μm; no less than 330 μm; no less than 340 μm; or no less than 350 μm.

As used herein, “strain” is the deformation of a material with stress (e.g., stretching). As used herein, “original length” is the length of a material (e.g., s sandwich-structured composite) before experiencing strain (e.g., stretching). Exemplary sandwich-structured composites are capable of being stretched to 120% of their original length at 50% strain. Furthermore, when exemplary sandwich-structured composites are stretched to 120% of their original length the composite's electrical properties are not compromised.

### II. EXEMPLARY ELECTRONIC DEVICES

Exemplary interconnects of the present disclosure may be incorporated into an electronic device. Suitable electronic devices include, but are not limited to, mobile devices, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices, servers, routers, electronic devices implemented in automotive vehicles (e.g., autonomous vehicles), or any other device that stores or retrieves data or computer instructions, or any combination thereof. In various instances, exemplary interconnects may be incorporated into a flexible battery. In some instances, exemplary interconnects may be incorporated into a wearable electronic device.

Exemplary electronic devices may include a semiconductor substrate comprising at least one integrated circuit (IC). In exemplary electronic devices, an interconnect of the present disclosure may connect at least two circuit elements in an integrated circuit (IC). In various instances, the integrated circuit (IC) may be soldered onto a printed circuit board (PCB) substrate within the electronic device.

### III. EXEMPLARY METHODS

Exemplary methods can be used to prepare interconnects. Various aspects of methods of preparing interconnects are described below.

A. Exemplary Methods of Preparing Interconnects

Exemplary methods of preparing interconnects may comprise preparing a sandwich-structured composite. Exemplary methods of preparing a sandwich-structured composite may comprise forming a first thermosetting polymer layer, forming a core layer on the first thermosetting polymer layer, and forming a second thermosetting polymer layer on the core layer.

Forming a first thermosetting polymer layer may comprise pouring a first thermosetting polymer mixture into a first mold. As used herein, a “mold” is a cavity or matrix in which a fluid or plastic substance is shaped into a desired finished product. The first thermosetting polymer mixture may comprise a first thermosetting polymer and a first curing agent. In various instances, the first curing agent may be a silicone curing agent, e.g., Dow SYLGARD™ 184 silicone curing agent.

The ratio of the first thermosetting polymer to the first curing agent may be between 5:1 and 15:1. In various instances, the ratio of the first thermosetting polymer to the first curing agent may be between 6:1 and 14:1; between 7:1 and 13:1; between 8:1 and 12:1; or between 9:1 and 11:1. In various instances, the ratio of the first thermosetting polymer to the first curing agent may be no greater than 15:1; no greater than 14:1; no greater than 13:1; no greater than 12:1; no greater than 11:1; no greater than 10:1; no greater than 9:1; no greater than 8:1; no greater than 7:1; no greater than 6:1; or no greater than 5:1. In various instances, the ratio of the first thermosetting polymer to the first curing agent may be no less than 5:1; no less than 6:1; no less than 7:1; no less than 8:1; no less than 9:1; no less than 10:1; no less than 11:1; no less than 12:1; no less than 13:1; no less than 14:1; or no less than 15:1.

Exemplary methods may further comprise curing the first thermosetting polymer layer.

Curing the first thermosetting polymer layer may occur at a temperature between 20° C. and 150° C. In various instances, curing the first thermosetting polymer layer may occur at a temperature between 25° C. and 145° C.; between 30° C. and 140° C.; between 35° C. and 135° C.; between 40° C. and 130° C.; between 45° C. and 125° C.; between 50° C. and 120° C.; between 55° C. and 115° C.; between 60° C. and 110° C.; between 65° C. and 105° C.; between 70° C. and 100° C.; between 75° C. and 95° C.; or between 80° C. and 90° C. In various instances, curing the first thermosetting polymer layer may occur at a temperature of no greater than 150° C.; no greater than 145° C.; no greater than 130° C.; no greater than 125° C.; no greater than 120° C.; no greater than 115° C.; no greater than 110° C.; no greater than 105° C.; no greater than 100° C.; no greater than 95° C.; or no greater than 20° C. In various instances, curing the first thermosetting polymer layer may occur at a temperature of no less than 20° C.; no less than 25° C.; no less than 30° C.; no less than 35° C.; no less than 40° C.; no less than 55° C.; no less than 60° C.; no less than 65° C.; no less than 70° C.; no less than 75° C.; no less than 80° C.; no less than 85° C.; no less than 90° C.; no less than 95° C.; no less than 100° C.; no less than 105° C.; no less than 110° C.; no less than 115° C.; no less than 120° C.; no less than 125° C.; no less than 130° C.; no less than 135° C.; no less than 140° C.; no less than 145° C.; or no less than 150° C.

Curing the first thermosetting polymer layer may occur for a total time period of 10 minutes to 48 hours. In various instances, curing the first thermosetting polymer layer may occur for a time period of 15 minutes to 45 hours; 20 minutes to 40 hours; 25 minutes to 35 hours; 30 minutes to 30 hours; 35 minutes to 25 hours; 40 minutes to 20 hours; 45 minutes to 15 hours; 50 minutes to 10 hours; 1 hour to 9 hours; 2 hours to 8 hours; 3 hours to 7 hours; or 4 hours to 6 hours. In various instances, curing the first thermosetting polymer layer may occur for a time period of no greater than 48 hours; no greater than 45 hours; no greater than 40 hours; no greater than 35 hours; no greater than 30 hours; no greater than 25 hours; no greater than 20 hours; no greater than 15 hours; no greater than 10 hours; no greater than 9 hours; no greater than 8 hours; no greater than 7 hours; no greater than 6 hours; no greater than 5 hours; no greater than 4 hours; no greater than 3 hours; no greater than 2 hours; no greater than 1 hour; no greater than 55 minutes; no greater than 50 minutes; no greater than 45 minutes; no greater than 40 minutes; no greater than 35 minutes; no greater than 30 minutes; no greater than 25 minutes; no greater than 20 minutes; no greater than 15 minutes; or no greater than 10 minutes. In various instances, curing the first thermosetting polymer may occur for a time period of no less than 10 minutes; no less than 15 minutes; no less than 20 minutes; no less than 25 minutes; no less than 30 minutes; no less than 35 minutes; no less than 40 minutes; no less than 45 minutes; no less than 50 minutes; no less than 55 minutes; no less than 1 hour; no less than 2 hours; no less than 3 hours; no less than 4 hours; no less than 5 hours; no less than 6 hours; no less than 7 hours; no less than 8 hours; no less than 9 hours; no less than 10 hours; no less than 15 hours; no less than 20 hours; no less than 25 hours; no less than 30 hours; no less than 35 hours; no less than 40 hours; no less than 45 hours; or no less than 48 hours.

Exemplary methods may further comprise placing metal tabs on top of the first thermosetting polymer layer before curing of the first thermosetting polymer layer is complete, followed by completing curing. The metal tabs may be placed on top of the first thermosetting polymer layer after curing the first thermosetting polymer layer for 20 minutes to 50 minutes. In various instances, the metal tabs may be placed on top of the first thermosetting polymer layer after curing the first thermosetting polymer layer for 25 minutes to 45 minutes or 30 minutes to 40 minutes. In various instances, the metal tabs may be placed on top of the first thermosetting polymer layer after curing the first thermosetting polymer layer for no greater than 50 minutes; no greater than 45 minutes; no greater than 40 minutes; no greater than 35 minutes; no greater than 30 minutes; no greater than 25 minutes; or no greater than 20 minutes. In various instances, the metal tabs may be placed on top of the first thermosetting polymer layer after curing the first thermosetting polymer layer for no less than 20 minutes; no less than 25 minutes; no less than 30 minutes; no less than 35 minutes; no less than 40 minutes; no less than 45 minutes; or no less than 50 minutes.

The metal tabs may comprise any suitable conductive metal. In various instances, the metal tabs may comprise copper.

Exemplary methods of preparing a sandwich-structured composite may further comprise forming a core layer on the first thermosetting polymer layer. Exemplary methods of forming a core layer may comprise preparing a core layer mixture. Preparing exemplary core layer mixtures may comprise adding a conductive metal and a solvent to a polymer.

Preparation of the core layer mixture may further comprise agitating the core layer mixture. Exemplary agitating operations may be achieved by sonication. In various instances, agitating the core layer mixture may occur for a time period of 60 minutes to 90 minutes. In various instances, agitating the core layer mixture may occur for a time period of 65 minutes to 90 minutes; 70 minutes to 90 minutes; 75 minutes to 85 minutes; 76 minutes to 84 minutes; 77 minutes to 83 minutes; 78 minutes to 82 minutes; or 79 minutes to 81 minutes. In various instances, agitating the core layer mixture may occur for a time period of no greater than 90 minutes; no greater than 85 minutes; no greater than 84 minutes; no greater than 83 minutes; no greater than 82 minutes; no greater than 81 minutes; no greater than 80 minutes; no greater than 79 minutes; no greater than 78 minutes; no greater than 77 minutes; no greater than 76 minutes; no greater than 75 minutes; no greater than 70 minutes; no greater than 65 minutes; or no greater than 60 minutes. In various instances, agitating the core layer mixture may occur for a time period of no less than 60 minutes; no less than 65 minutes; no less than 70 minutes; no less than 75 minutes; no less than 76 minutes; no less than 77 minutes; no less than 78 minutes; no less than 79 minutes; no less than 80 minutes; no less than 81 minutes; no less than 82 minutes; no less than 83 minutes; no less than 84 minutes; no less than 85 minutes; or no less than 90 minutes.

Exemplary methods of forming a core layer may further comprise pouring the core layer mixture onto the first thermosetting layer to form the core layer. Exemplary methods may further comprise drying the core layer.

Drying the core layer may occur at a temperature between 20° C. and 30° C. In various instances, drying the core layer may occur at a temperature between 21° C. and 29° C.; between 22° C. and 28° C.; between 23° C. and 27° C.; or between 24° C. and 26° C. In various instances, drying the core layer may occur at a temperature of no greater than 30° C.; no greater than 29° C.; no greater than 28° C.; no greater than 27° C.; no greater than 26° C.; no greater than 25° C.; no greater than 24° C.; no greater than 23° C.; no greater than 22° C.; no greater than 21° C.; or no greater than 20° C. In various instances, drying the core layer may occur at a temperature of no less than 20° C.; no less than 21° C.; no less than 22° C.; no less than 23° C.; no less than 24° C.; no less than 25° C.; no less than 26° C.; no less than 27° C.; no less than 28° C.; no less than 29° C.; or no less than 30° C.

Drying the core layer may occur for a time period of 24 hours to 48 hours. In various instances, the core layer may occur for a time period of 25 hours to 45 hours; 25 hours to 40 hours; 30 hours to 40 hours; 31 hours to 39 hours; 32 hours to 38 hours; 33 hours to 37 hours; or 34 hours to 36 hours. In various instances, drying the core layer may occur for a time period of no greater than 48 hours; no greater than 45 hours; no greater than 40 hours; no greater than 39 hours; no greater than 38 hours; no greater than 37 hours; no greater than 36 hours; no greater than 35 hours; no greater than 34 hours; no greater than 33 hours; no greater than 32 hours; no greater than 31 hours; no greater than 30 hours; no greater than 25 hours; or no greater than 24 hours. In various instances, drying the core layer may occur for a time period of no less than 24 hours; no less than 25 hours; no less than 30 hours; no less than 31 hours; no less than 32 hours; no less than 33 hours; no less than 34 hours; no less than 35 hours; no less than 36 hours; no less than 37 hours; no less than 38 hours; no less than 39 hours; no less than 40 hours; no less than 45 hours; or no less than 48 hours.

Exemplary methods of preparing a sandwich-structured composite may further comprise forming a second thermosetting polymer layer on the core layer. Forming a first thermosetting polymer layer may comprise pouring a second thermosetting polymer mixture onto the core layer. The second thermosetting polymer mixture may comprise a second thermosetting polymer and a second curing agent. In various instances, the second curing agent may be a silicone curing agent, e.g., Dow SYLGARD™ 184 silicone curing agent.

The ratio of the second thermosetting polymer to the second curing agent may be between 5:1 and 15:1. In various instances, the ratio of the second thermosetting polymer to the second curing agent may be between 6:1 and 14:1; between 7:1 and 13:1; between 8:1 and 12:1; or between 9:1 and 11:1. In various instances, the ratio of the second thermosetting polymer to the second curing agent may be no greater than 15:1; no greater than 14:1; no greater than 13:1; no greater than 12:1; no greater than 11:1; no greater than 10:1; no greater than 9:1; no greater than 8:1; no greater than 7:1; no greater than 6:1; or no greater than 5:1. In various instances, the ratio of the second thermosetting polymer to the second curing agent may be no less than 5:1; no less than 6:1; no less than 7:1; no less than 8:1; no less than 9:1; no less than 10:1; no less than 11:1; no less than 12:1; no less than 13:1; no less than 14:1; or no less than 15:1.

Curing the second thermosetting polymer layer may occur at a temperature between 20° C. and 30° C. In various instances, curing the second thermosetting polymer layer may occur at a temperature between 21° C. and 29° C.; between 22° C. and 28° C.; between 23° C. and 27° C.; or between 24° C. and 26° C. In various instances, curing the second thermosetting polymer layer may occur at a temperature of no greater than 30° C.; no greater than 29° C.; no greater than 28° C.; no greater than 27° C.; no greater than 26° C.; no greater than 25° C.; no greater than 24° C.; no greater than 23° C.; no greater than 22° C.; no greater than 21° C.; or no greater than 20° C. In various instances, curing the second thermosetting polymer layer may occur at a temperature of no less than 20° C.; no less than 21° C.; no less than 22° C.; no less than 23° C.; no less than 24° C.; no less than 25° C.; no less than 26° C.; no less than 27° C.; no less than 28° C.; no less than 29° C.; or no less than 30° C.

Curing the second thermosetting polymer layer may occur for a time period of 60 hours to 80 hours. In various instances, curing the second thermosetting polymer layer may occur for a time period of 60 hours to 75 hours; 65 hours to 75 hours; 66 hours to 74 hours; 67 hours to 73 hours; 68 hours to 72 hours; or 69 hours to 71 hours. In various instances, curing the second thermosetting polymer layer may occur for a time period of no greater than 80 hours; no greater than 75 hours; no greater than 74 hours; no greater than 73 hours; no greater than 72 hours; no greater than 71 hours; no greater than 70 hours; no greater than 69 hours; no greater than 68 hours; no greater than 67 hours; no greater than 66 hours; no greater than 65 hours; or no greater than 60 hours. In various instances, curing the second thermosetting polymer layer may occur for a time period of no less than 60 hours; no less than 65 hours; no less than 66 hours; no less than 67 hours; no less than 68 hours; no less than 69 hours; no less than 70 hours; no less than 71 hours; no less than 72 hours; no less than 73 hours; no less than 74 hours; no less than 75 hours; or no less than 80 hours.

B. Exemplary Methods of Making Electronic Devices

Exemplary electronic devices comprising interconnects of the present disclosure may be manufactured using methods known to those of skill in the art. Exemplary electronic devices may be constructed in various ways depending on the specific device and intended use for said device.

### IV. EXPERIMENTAL EXAMPLES

Without limiting the scope of the instant disclosure, various experimental examples of embodiments discussed above were prepared and the results are discussed below.

Abbreviations that may be used in the examples that follow are:

min or min. is minute(s);
h or h. is hour(s);
rt, RT, or r.t. is room temperature;
Ag is silver;
NPs is nanoparticles;
NCs is nanocrystals;
NWs is nanowires;
Cu is copper;
GO is graphene oxide;
CNC is cellulose nanocrystals;
CNT is carbon nanotubes;
PVDF-HFP is poly(vinylidene fluoride-co-hexafluoropropylene);
PDMS is polydimethylsiloxane;
PUA is poly(urethane acrylate); and
SEBS is styrene-ethylene-butylene-styrene.

### Example 1: Method for Preparing an Exemplary Sandwich-Structured Composite

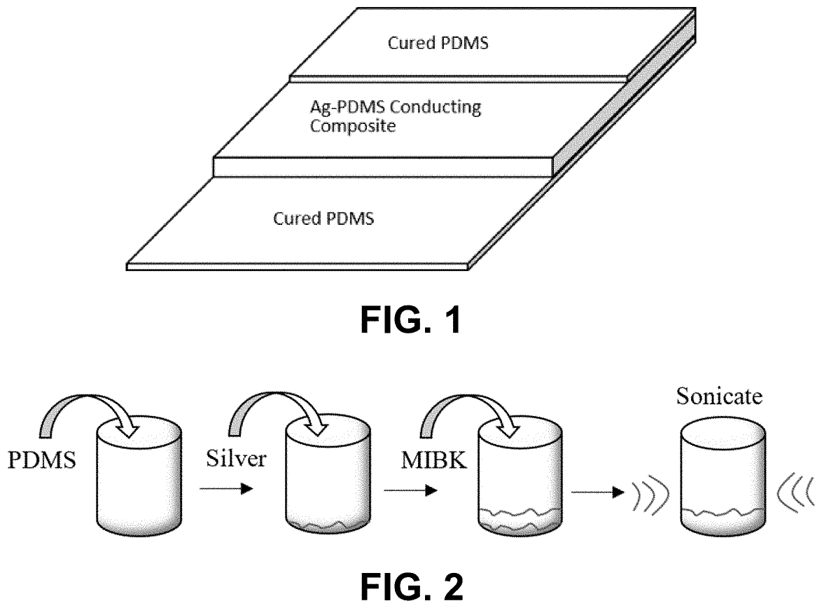

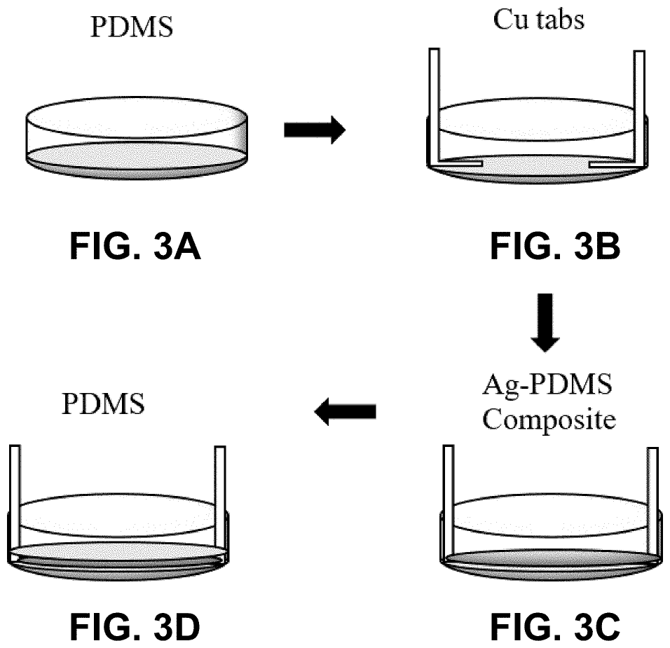

A sandwich-structured, conductive, flexible, and stretchable sandwich-structured composite may be prepared as described below. This sandwich-structured composite may be used as an interconnect. As illustrated in FIG. 1, the sandwich-structured composite consists of 3 layers with an Ag-PDMS core layer sandwiched between two layers of cured PDMS. The Ag-PDMS core layer acts as the conducting layer while the cured PDMS layers provide mechanical robustness with extensive flexing, stretching, and high temperature tolerance. The sandwich structure of the composite functions to protect the Ag-PDMS core layer. A conductive stretchable interconnect was prepared with Ag flakes and PDMS. The silver (Ag) conductive composite with polydimethylsiloxane (PDMS) as the adhesive ensured that the silver flakes were held in place in between two protective layers of mechanically robust yet stretchable PDMS. This exemplary method is schematically illustrated in FIGS. 3A-3D.

A. Preparation of an Ag-PDMS Composite for an Exemplary Core Layer

As illustrated in FIG. 2, silver flakes (Ag, <10 μm, 99.9% metals basis) (88% by weight) were mixed into PDMS (Slygard 184) (12% by weight), and methyl-isobutyl-ketone (MIBK) was added to the mixture as a solvent. The mixture was then sonicated for 70 minutes. Silver flakes were used as the conductive metal filler. PDMS was used as the polymer matrix due to its adhesive properties to bind the silver flakes together inside the structure.

B. Preparation of an Exemplary First Thermosetting Polymer Layer

Polydimethylsiloxane (PDMS) was mixed with the curing agent (Dow SYLGARD™ 184 silicone curing agent) in a ratio of 10:1 and the mixture was spin coated inside a glass petri-dish. The mixture of PDMS and curing agent was left to cure in the heating oven at 60° C. for 40 minutes. 0.5 cm×2 cm of 0.02 mm thin copper foils were placed with 1 cm on top of the dry base PDMS film to connect with the Ag-PDMS core layer and the rest of the length outside the petri-dish as tabs. FIG. 3B schematically illustrates the copper tabs on the base PDMS film. The PDMS film was then left at 60° C. for 60 minutes to completely cure.

C. Preparation of an Exemplary Sandwich-Structured Composite

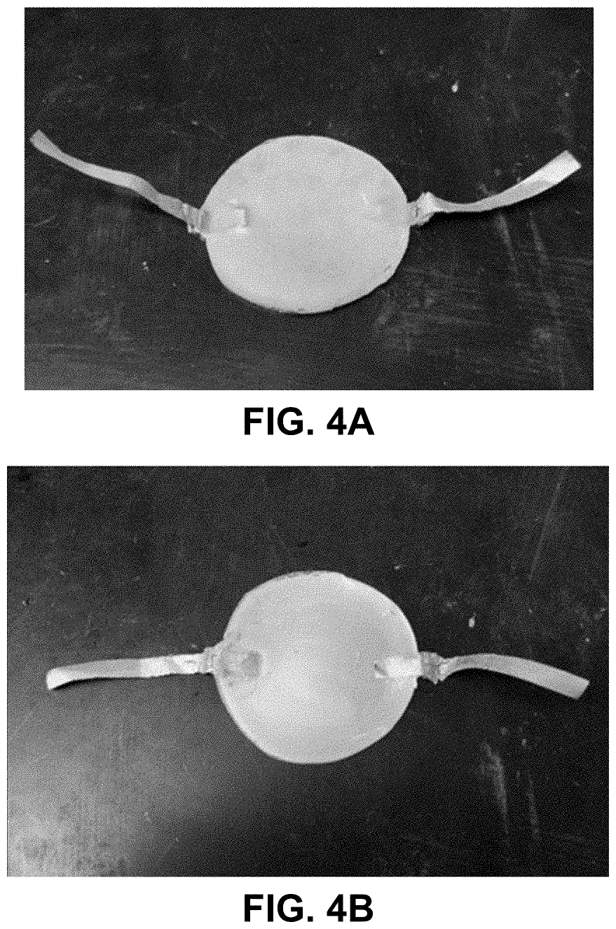

The sonicated Ag-PDMS composite was spin coated onto the cured PDMS substrate with Cu tabs attached on top and was left to dry at room temperature for 48 hours. Another layer of PDMS with curing agent (Dow SYLGARD™ 184 silicone curing agent) in a ratio of 10:1 was spin coated on top of the Ag-PDMS layer to form a second PDMS layer. The PDMS and curing agent mixture was cured at room temperature over a period of 72 hours. After the PDMS layer had completely cured, the resultant cured sandwich-structured composite was peeled from the petri-dish. FIGS. 4A-4B show the top and bottom layer view of the Ag-PDMS sandwich-structured composite that was peeled from the petri-dish. The conducting Ag-PDMS core layer within the sandwich structure was measured to be 50 μm thick. When repeated, this method of preparing the sandwich structure having an Ag-PDMS core layer yielded consistent electrical and mechanical results.

### Example 2: Electrical Characterization of an Exemplary Core Layer

The sheet resistance of the Ag-PDMS layer (the core layer) was measured with a four-point probe, from Semiprobe, to be 19.3 mΩ/sq. The resistivity of the conducting layer (the core layer) was calculated to be 9.202 μΩ·cm with the formula ρ=R_{S}*thickness of the layer, where R_{S} is the measured sheet resistance. The conductivity was further calculated with the formula σ=ρ⁻¹ to be 1.08*10⁵ S·cm⁻¹.

### Example 3: Mechanical Characterization

A. Bending Fatigue Test

The bending fatigue test was carried out for the sandwich-structured composite comprising the Ag-PDMS core layer. The bending fatigue test is used to evaluate a flexible electronic device's ability to withstand extensive bending and flexing cycles over the course of a lifetime of the device. This test is commonly used in the flexible electronics industry to test interconnects, batteries, and other components of wearable devices.

Rectangular samples, cut from the circular sandwich-structured composites, were sandwiched between two polycarbonate sheets and their ends were clamped in between beams on the bending machine. The bending machine was operated for 3,000 cycles at 90°. Optical microscopic images of the samples were taken before and after each test. The images were taken precisely near the areas of maximum induced stress while bending to observe mechanical deformations.

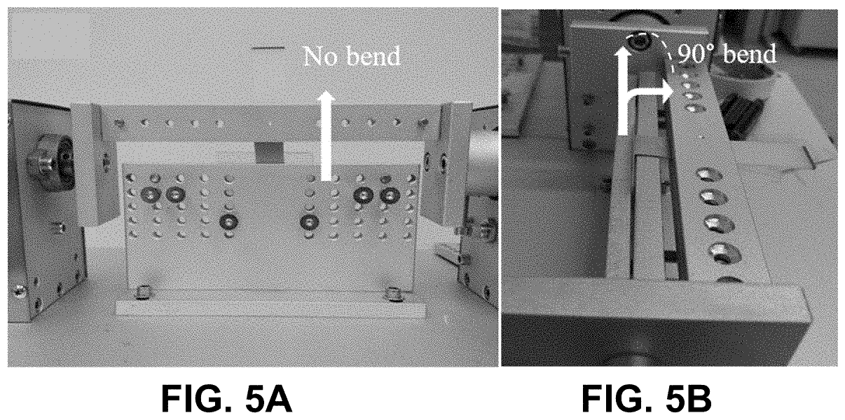

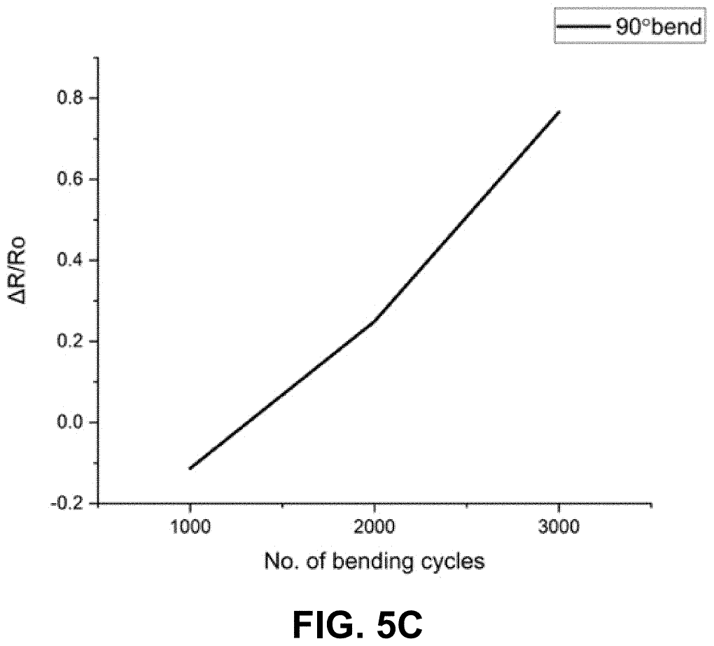

No bend or crease was observed on the sandwich-structured composite with the Ag-PDMS core layer after 3,000 cycles at 90°. The bending radius was not considered since the sample bent over the edge of a beam as shown in FIG. 5B. The end-to-end resistance was measured using a 2-point DC probe after every 1,000 bending cycles. A plot of ΔR/Ro against the number of bending cycles showed negative ΔR/Ro after 1,000 cycles (FIG. 5C). This data is supported by percolation theory, where re-alignment of the silver particles initially upon bending creates a better conducting path.

B. Stretch Test

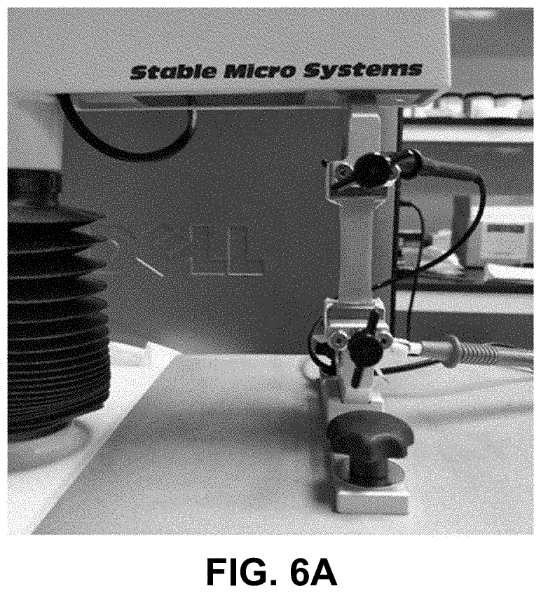

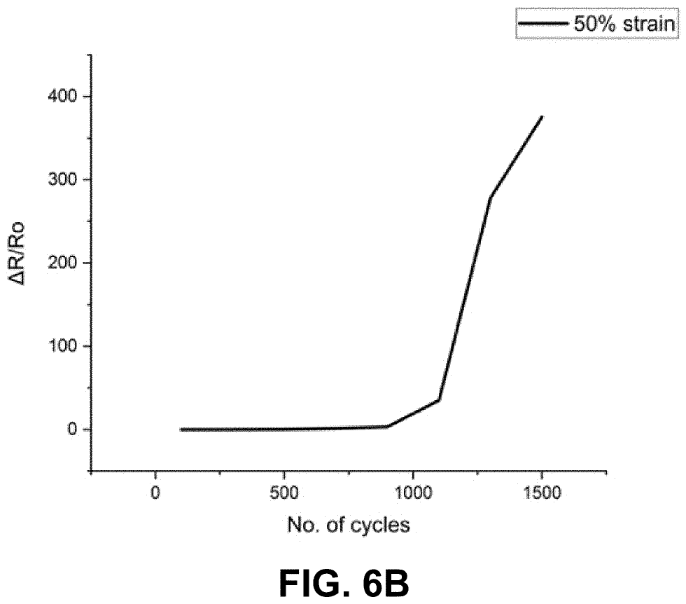

A Ta.XT texture analyzer was used for the uniaxial stretch test. For the uniaxial stretch test, the sandwich structure with the Ag-PDMS core layer was stretched up to 120% its original length at 0.01 mm·sec⁻¹, after which it ruptured from the point of attachment of the copper tabs into the PDMS. This rupturing may be attributed to the polymer curing process developing a weak area in adhesion at the contact points in an otherwise uniform structure. Stretch tests were performed on the samples up to 50% strain for 1,500 cycles and the change in resistance was observed after every 200 cycles. A plot of ΔR/Ro against the number of stretching cycles showed negative to no change in resistance until 700 cycles following which there was a steep increase (FIG. 6B). This initial trend in the change in resistance was similar to the bending tests where the re-alignment of the silver particles upon stretching led to the formation of better conducting paths.

### Example 4: Formation of an Exemplary Sandwich-Structure Composite with Modified Dimensions

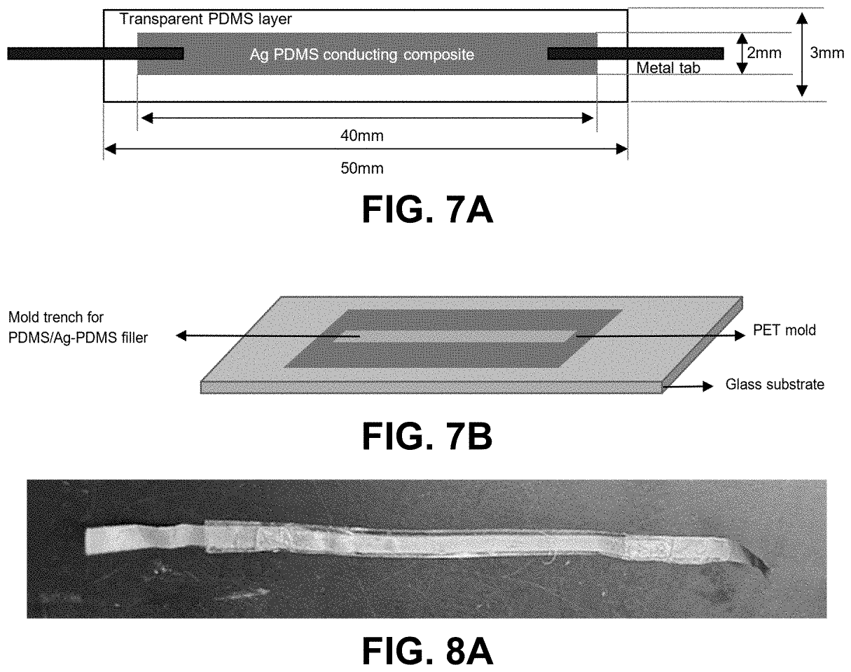

Keeping the layered structure and Ag-PDMS core layer unchanged from Example 1 Section 1, a material with modified dimensions, 5 mm×3 mm with a thickness of ˜200 μm, as illustrated in FIG. 7A, was fabricated, which is more suitable to be used as interconnects.

A. Preparation of Exemplary First Thermosetting Polymer Layer

As illustrated in FIG. 7B, a polyethylene terephthalate (PET) mold with an effective thickness (including adhesive back) of 50 μm with a 3 mm×50 mm trench in the center was cut and adhered on top of a glass substrate. Next, polydimethylsiloxane (PDMS) was mixed with the curing agent in a ratio of 10:1, poured into the PET mold trench, and was allowed to partially cure in the heating oven at 60° C. for 30 minutes. 2 mm×20 mm of 0.02 mm thick copper foils were then placed on either end of the base PDMS film (the first thermosetting polymer later) to connect with the Ag-PDMS layer (the core layer) and the rest of the length outside the molds as tabs. The film was then left at 60° C. for 60 minutes to completely cure.

B. Preparation of an Exemplary Sandwich-Structured Composite

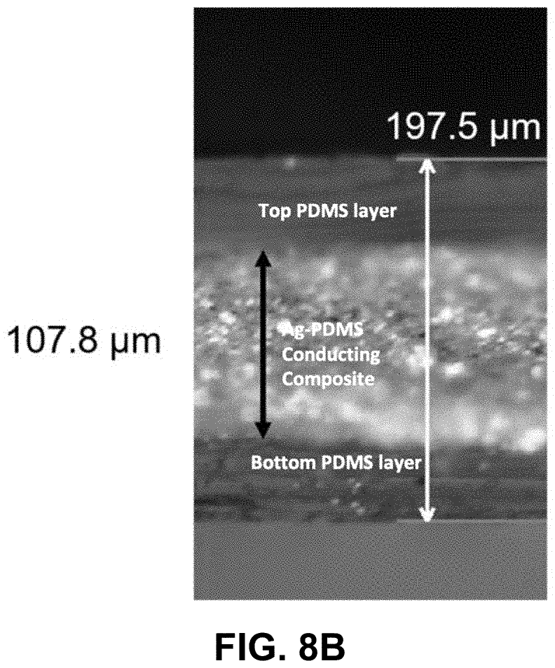

A second mold with an effective thickness (including adhesive back) of 100 μm with a 2 mm×40 mm trench in the center was adhered on top of the base mold. The sonicated Ag-PDMS composite was poured onto the cured PDMS substrate with Cu tabs attached on top and left to dry at room temperature for 48 hours. A third mold with the same dimensions of the base layer (effective thickness of 50 μm with a 3 mm×50 mm trench) was adhered to the Ag-PDMS core layer, and a mixture of PDMS and curing agent (10:1 ratio) was poured on top to form the second thermosetting polymer layer. The second thermosetting polymer layer was then cured at room temperature over a period of 72 hours. As illustrated in FIG. 8A, the smaller trench of the sandwiched layer (2 mm×40 mm trench) ensured that the Ag-PDMS composite (i.e., core layer) is encapsulated by cured PDMS on all sides. The Ag-PDMS sandwich structure (i.e., the sandwich-structure composite) was then removed from the mold. As shown in FIG. 8B, the conducting Ag-PDMS core layer within the sandwich structure was measured to be 108 μm thick. When repeated, this method of preparing the sandwich structure using a PET mold yielded consistent thickness and electrical and mechanical results.

What is claimed is:

1. An interconnect, comprising:
a sandwich-structured composite, comprising:
a first thermosetting polymer layer;
a second thermosetting polymer layer; and
a core layer between two thermosetting polymer layers, the core layer comprising:
80 weight % (wt %) to 95 wt % conductive metal; and
a polymer.

2. The interconnect of claim 1, wherein each thermosetting polymer layer comprises polydimethylsiloxane (PDMS).

3. The interconnect of claim 1, wherein the conductive metal comprises silver (Ag) flakes.

4. The interconnect of claim 1, wherein the polymer comprises polydimethylsiloxane (PDMS).

5. The interconnect of claim 1, wherein the core layer has a thickness between 50 μm and 110 μm.

6. The interconnect of claim 1, wherein the sandwich-structured composite has a thickness between 150 μm and 350 μm.

7. The interconnect of claim 1, wherein the sandwich-structured composite has a thickness between 200 μm and 300 μm.

8. The interconnect of claim 1, wherein the core layer has a conductivity of at least 1.05*10⁵ S·cm⁻¹.

9. The interconnect of claim 1, wherein the sandwich-structured composite is capable of being stretched to 120% of an original length of the sandwich-structured composite at 50% strain without losing electrical properties.

10. An electronic device comprising an interconnect, comprising:
a sandwich-structured composite, comprising:
a first thermosetting polymer layer;
a second thermosetting polymer layer; and
a core layer between two thermosetting polymer layers, the core layer comprising:
80 wt % to 95 wt % silver (Ag); and
polydimethylsiloxane (PDMS); wherein
the interconnect connects at least two circuit elements in an integrated circuit (IC).

11. The electronic device of claim 10, wherein the first thermosetting polymer layer and the second thermosetting polymer layer comprises polydimethylsiloxane (PDMS).

12. The electronic device of claim 10, wherein the core layer comprises 80 wt % to 90 wt % silver (Ag).

13. The electronic device of claim 10, wherein the silver (Ag) is present in the form of flakes.

14. A method of making an interconnect, the method comprising:
pouring a first thermosetting polymer mixture into a first mold to form a first thermosetting polymer layer, the first thermosetting polymer mixture comprising:
a first thermosetting polymer; and
a first curing agent;
curing the first thermosetting polymer layer;
preparing a core layer mixture, the core layer mixture comprising:
80 wt % to 95 wt % conductive metal;
a polymer; and
a solvent;
pouring the core layer mixture onto the first thermosetting layer to form a core layer,
drying the core layer;
pouring a second thermosetting polymer mixture onto the core layer to form a second thermosetting polymer layer, the second thermosetting polymer mixture comprising:
a second thermosetting polymer; and
a second curing agent; and
curing the second thermosetting polymer layer.

15. The method of claim 14, wherein the first thermosetting polymer and the second thermosetting polymer are each PDMS.

16. The method of claim 14, wherein curing the first thermosetting polymer layer occurs at a temperature between 20° C. and 150° C.

17. The method of claim 14, wherein curing the second thermosetting polymer layer occurs at a temperature between 20° C. and 30° C.

18. The method of claim 14, wherein curing the first thermosetting polymer layer occurs for a time period of 10 minutes to 48 hours.

19. The method of claim 14, wherein curing the second thermosetting polymer layer occurs for a time period of 60 hours to 80 hours.

20. A method of making an electronic device, the method comprising the method of claim 14.
